(19) United States
(12) Patent Application Publication
(10) Pub. No.: US 2015/0002967 A1
(43) Pub. Date: Jan. 1, 2015

(54) SEMICONDUCTOR DEVICE

(71) Applicant: KABUSHIKI KAISHA TOSHIBA, Tokyo (JP)

(72) Inventors: Minoru KAWASE, Yokohama Kanagawa (JP); Hideaki SAI, Ibo Hyogo (JP); Shigehiro HOSOI, Kawasaki Kanagawa (JP)

(21) Appl. No.: 14/306,507

(22) Filed: Jun. 17, 2014

(30) Foreign Application Priority Data
Jun. 28, 2013 (JP) 2013-137229

(51) Int. Cl. H01L 27/02; H02H 9/04

(52) U.S. Cl. CPC H01L 27/0248; H02H 9/046
USPC 361/56; 257/132

(57) ABSTRACT

A semiconductor device includes a first terminal and a second terminal at which a signal line is attachable. A first diode is connected between the first and second terminals with an anode connected to the first terminal. A second diode and a third diode are connected in series with each other and in parallel with the first diode between the first and second terminals. The second diode has an anode connected to the second terminal, and the third diode has an anode connected to the first terminal. The third diode is a Zener diode having a capacitance that is greater than each of a capacitance of the first diode and a capacitance of the second diode. A fourth diode is optionally included in series with the first diode or in series between the second and third diodes.

### CROSS-REFERENCE TO RELATED APPLICATION

This application is based upon and claims the benefit of priority from Japanese Patent Application No. 2013-137229, filed Jun. 28, 2013, the entire contents of which are incorporated herein by reference.

### FIELD

Embodiments described herein relate generally to a semiconductor device.

### BACKGROUND

Exchange of information between information processing apparatuses is performed through interfaces. The interfaces are electrically connected to integrated circuits in the information processing apparatuses through input/output terminals. The integrated circuits in information processing apparatuses might be damaged by electrostatic discharge (ESD) at the input/output terminals. Generally, devices for protection against ESD are connected between the input/output terminals and ground terminals in the information processing apparatuses. In order to protect the integrated circuits from overvoltage, the breakdown voltages of the ESD protection devices are set to be values slightly higher than the normal voltages of input/output signals. For example, if the voltage of an input/output signal is 5 V, the breakdown voltage of a device for protection from ESD may be set to about 7 V.

As the breakdown voltage of an ESD protection device decreases, the electrostatic capacitance of ESD protection device increases. When the electrostatic capacitance of the ESD protection device increases, the impedance decreases, and an input/output signal may leak though the ESD protection device. As the frequency of a signal carrying an interface increases, the impedance further decreases. For this reason, the electrostatic capacities of ESD protection devices are required to be reduced.

However, a device for protection from ESD includes a diode. For this reason, in order to reduce the electrostatic capacitance, it is necessary to reduce the area of the p-n junction of the diode, but the on-resistance increases. If the on-resistance of the ESD protection device is high, when ESD occurs, a current flowing in the ESD protection device decreases, and a current flowing on the integrated circuit side increases. As a result, the ESD tolerance of an information processing apparatus including the ESD protection device decreases. An ESD protection device having a low electrostatic capacitance and a low on-resistance is desirable.

### DESCRIPTION OF THE DRAWINGS

FIG. 1 is a diagram illustrating an equivalent circuit of a semiconductor device according to a first embodiment.

FIG. 2 is a plan view depicting the semiconductor device according to the first embodiment.

FIG. 3 is a cross-sectional view of the semiconductor device according to the first embodiment taken along a line A-A′ of FIG. 2.

FIG. 4 is a diagram illustrating an equivalent circuit of a semiconductor device according to a second embodiment.

FIG. 5 is a cross-sectional view of the semiconductor device according to the second embodiment.

### DETAILED DESCRIPTION

An object of the present disclosure is to provide a semiconductor device having a low electrostatic capacitance and a low on-resistance.

According to an embodiment, a semiconductor device, which may be an electrostatic protection device, includes a first terminal at a first potential and a second terminal at which a signal line is attachable. A first diode is connected between the first and second terminals with an anode connected to the first terminal. A second diode and a third diode are connected in series with each other and in parallel with the first diode between the first and second terminals. The second diode has an anode connected to the second terminal, and the third diode has an anode connected to the first terminal. The third diode is a Zener diode having a capacitance that is greater than each of a capacitance of the first diode and a capacitance of the second diode. A fourth diode is optionally included in series with the first diode or in series between the second and third diodes.

In general, according to one embodiment, a semiconductor device includes: a first anode layer (first semiconductor layer); a first cathode layer (first semiconductor region) formed on the first anode layer; a first-conductivity-type second semiconductor layer (sixth semiconductor region) formed on the first anode layer to surround the first cathode layer; a fourth cathode layer (fifth semiconductor region) formed on a front surface of the first cathode layer; a fourth anode layer (fourth semiconductor region) formed between the first cathode layer and the fourth cathode layer; a second cathode layer (seventh semiconductor region) formed on the first anode layer; a second-conductivity-type third semiconductor layer (second semiconductor region) formed on the first anode layer to surround the second cathode layer; a third cathode layer (a third semiconductor region) that is formed to intervene in the second cathode layer, the third semiconductor layer, and the first anode layer, and that has a dopant concentration higher than the dopant concentration of the second cathode layer; a second anode layer (eighth semiconductor region) formed on the second cathode layer; a first electrode electrically connected to the first anode layer; and a second electrode electrically connected to the fourth cathode layer and the second anode layer.

In general, according to another embodiment, a semiconductor device includes: a first anode layer (first semiconductor layer); a first cathode (first semiconductor region) layer formed on the first anode layer; a second cathode layer (seventh semiconductor region) formed on the first anode layer; a first-conductivity-type second semiconductor layer (fourth semiconductor region) that is formed on the first anode layer to surround the second cathode layer; a fourth cathode layer (fifth semiconductor region) formed on a front surface of the second cathode layer; a fourth anode layer (sixth semiconductor region) formed between the second cathode layer and the fourth cathode layer; a third cathode layer (third semiconductor region) that is formed to below the second cathode layer and above the first anode layer, and that has a dopant concentration higher than a dopant concentration of the second cathode layer; a second anode layer (eight semiconductor region) formed on the second cathode layer; a first electrode electrically connected to the first anode layer; and a second electrode electrically connected to the first cathode layer and the second anode layer.

Hereinafter, embodiments of the present disclosure will be described with reference to the accompanying drawings. The drawings to be used in descriptions of the embodiments are schematic drawings for facilitating the descriptions, and the shapes, dimensions, magnitude relations, and the like of individual components in the embodiments are not necessarily limited to those shown in the drawings, and may be appropriately changed within a range in which effects of the present disclosure may be achieved. In general, description will be provided of examples in which a first conductivity type is a p-type and a second conductivity type is an n-type; however, but devices in which the first conductivity type may be the n-type and the second conductivity type may be the p-type are also contemplated and disclosed. As an example of a semiconductor material, silicon (Si) will be described; however, the present disclosure may also be applied to other semiconductor materials such as a compound semiconductor such as silicon carbide (SiC) or gallium nitride (GaN). As an example of the material of an insulating film, silicon oxide (SiO₂) will be described; however, other insulators such as silicon nitride (SiN), silicon oxynitride, and alumina (Al₂O₃) may also be incorporated. When conductivity types of the n-type are denoted by n+, n, and n−, n-type these designations indicate dopant concentrations at different concentration levels and the relative n-type dopant concentrations decrease from high to low in the order of n+, n, and n−. Similarly, p+, p, and p− indicate dopant concentrations at different concentration levels and the relative p-type dopant concentrations decrease from high to low in the order of p+, p, and p−.

### First Embodiment

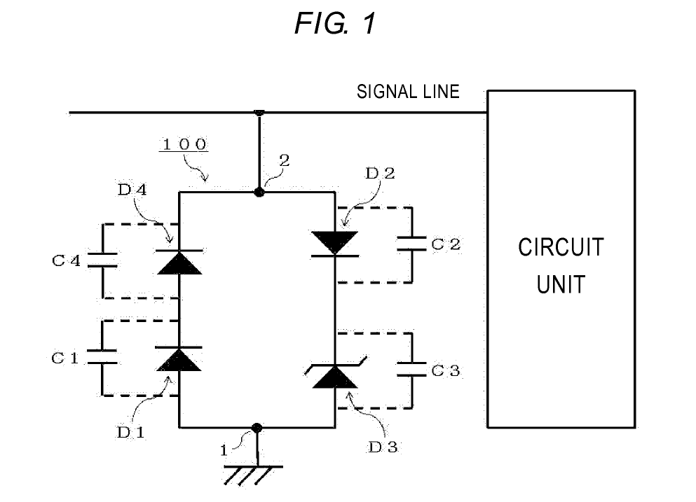

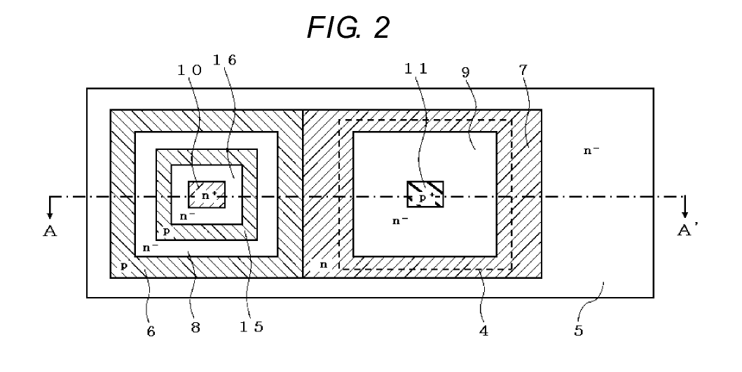

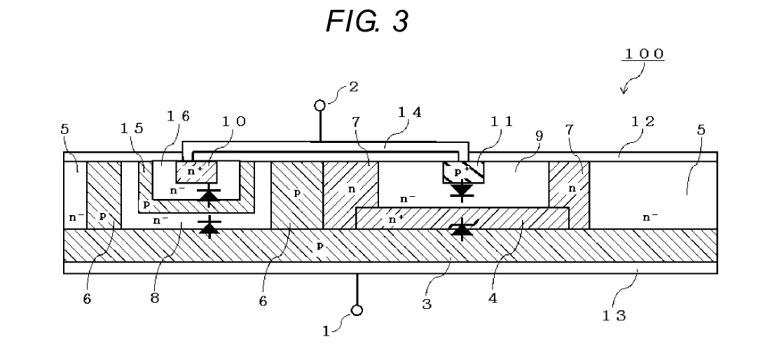

With reference to FIGS. 1 to 3, a semiconductor device 100 according to a first embodiment of the present disclosure will be described. FIG. 1 is a view illustrating an equivalent circuit of the semiconductor device according to the first embodiment, and FIG. 2 is a plan view depicting the semiconductor device according to the first embodiment, and FIG. 3 is a cross-sectional view of the semiconductor device according to the first embodiment taken along a line A-A′ of FIG. 2. In the plan view of FIG. 2, an insulating layer 12 and a second electrode 14 are not specifically depicted.

As shown in FIG. 1, the semiconductor device 100 according to the first embodiment is provided, for example, connected between a ground terminal and a signal line that connects an input/output terminal to a circuit unit. If a voltage exceeding a predetermined rated value of the input/output signal is applied to the signal line, excess electric current is discharged to the ground terminal through the semiconductor device 100. That is, in FIG. 1, the excess electric charge applied to the signal line flows from a second terminal 2 to a first terminal 1. As a result, when ESD (electrostatic discharge) occurs at an input/output signal line, the circuit unit is protected from ESD by the semiconductor device 100.

The semiconductor device 100 includes the first terminal 1, the second terminal 2, a diode D1 (a first diode), a diode D2 (a second diode), a Zener diode D3, and a diode D4 (a fourth diode). The first terminal 1 is electrically connected to a ground terminal (ground potential). The second terminal 2 is electrically connected to a signal line that is connected to the circuit unit.

The anode of the diode D1 is electrically connected to the first terminal 1. The cathode of the diode D1 is electrically connected to the anode of the diode D4. The cathode of the diode D4 is electrically connected to the second terminal 2. The anode of the diode D2 is electrically connected to the second terminal 2. The cathode of the diode D2 is electrically connected to the cathode of the Zener diode D3. The anode of the Zener diode D3 is electrically connected to the first terminal 1.

Here, the diode D1, the diode D2, the Zener diode D3, and the diode D4 have electrostatic capacitance C1, electrostatic capacitance C2, electrostatic capacitance C3, and electrostatic capacitance C4, respectively. In this case, since the diode D3 is a Zener diode, the electrostatic capacitance C3 is considerably larger than the electrostatic capacities C1, C2, and C4.

When a negative overvoltage is applied to the signal line, discharge occurs through the diode D1 and the diode D4. Also, if a positive overvoltage is applied to the signal line, when the positive overvoltage exceeds the breakdown voltage of the Zener diode D3, discharge occurs through the diode D2 and the Zener diode D3. Therefore, the circuit unit is protected by the semiconductor device 100 from negative voltages applied to the signal line and positive voltages that are equal to or higher than the breakdown voltage of the Zener diode D3. For example, if a typical input/output signal is 5 V, the Zener diode D3 may be designed such that the breakdown voltage of the Zener diode D3 is about 7 V.

The Zener diode D3 can be used alone as an ESD protection. However, since the breakdown voltage of the Zener diode D3 is considerably higher than the breakdown voltages of the diode D1 and the diode D2, the Zener diode D3 has an electrostatic capacitance considerably higher than those of the diode D1, the diode D2, and the diode D4. For this reason, when the frequency of an input/output signal increases, the impedance relative to the input/output signal of the Zener diode D3 is significantly reduced. As a result, the high frequency input/output signal may leak through a lone Zener diode D3, making it not suitable to use the Zener diode D3 alone as an ESD protection device for a device operating at a high frequency.

As described above, the semiconductor device 100 according to the present embodiment includes the diode D1, the diode D2, the Zener diode D3, and the diode D4. Since the diode D2 and the Zener diode D3 are connected in series, even when the electrostatic capacitance of the Zener diode D3 is set to be high, the electrostatic capacitance of the lone Zener diode D3 does not substantially influence the value of the effective electrostatic capacitance of the semiconductor device 100. Also, since the diode D1 and the diode D4 are connected in parallel to the diode D2, the electrostatic capacitance of the semiconductor device 100 is the sum of the electrostatic capacitance of the diode D1, the electrostatic capacitance of the diode D2, and the electrostatic capacitance of the diode D4. Therefore, in the semiconductor device 100 according to the present embodiment, even when the breakdown voltage is set to be low by the Zener diode D3, since the effective electrostatic capacitance of the semiconductor device 100 is determined by the diode D1, the diode D2, and the diode D4, and the value of electrostatic capacitance of the semiconductor device 100 may be kept low.

A structural example of semiconductor device 100 will be described with reference to FIGS. 2 and 3. The semiconductor device 100 includes the first terminal 1, the second terminal 2, a first anode layer 3, a third cathode layer 4, an n⁻-type first semiconductor layer 5, a p-type second semiconductor layer 6, an n-type third semiconductor layer 7, a first cathode layer 8, a second cathode layer 9, an n⁺-type contact layer 10, a second anode layer 11, an insulating layer 12, a first electrode 13, a second electrode 14, a fourth anode layer 15, and a fourth cathode layer 16. The above-described individual semiconductor layers are formed of, for example, silicon.

The third cathode layer 4 is formed on a portion of the first anode layer 3. The n-type dopant concentration of the third cathode layer 4 is, for example, 1×10¹⁹/cm³ to 1×10²⁰/cm³. Also, the third cathode layer 4 is formed to have a predetermined planar pattern (for example, a rectangular planar pattern). The p-type dopant concentration of the first anode layer 3 is, for example, 1×10¹⁸/cm³ to 1×10¹⁹/cm³. As a p-type dopant, for example, boron (B) may be used. Also, as an n-type dopant, for example, phosphorus (P) or arsenic (As) may be used.

The n⁻-type first semiconductor layer 5 is epitaxially grown on the first anode layer 3 to cover the third cathode layer 4. The n⁻-type first semiconductor layer 5 has an n-type dopant concentration lower than the n-type dopant concentration of the third cathode layer 4. The n-type dopant concentration of the n⁻-type first semiconductor layer 5 is, for example, 1×10¹⁴/cm³ to 1×10¹⁵/cm³.

The p-type second semiconductor layer 6 is formed in a frame shape surrounding n+-type contact layer 10 when viewed from above, as in FIG. 2. The p-type semiconductor layer 6 extends from an upper surface of the n⁻-type first semiconductor layer 5 to the first anode layer 3. That is, as depicted in FIG. 2, the p-type second semiconductor layer 6 has a rectangular frame shape and extends vertically (into the page of FIG. 2 or from page top to page bottom direction in FIG. 3) towards the first anode layer 3 while maintaining the rectangular frame shape through depth, and reaches the top surface of the first anode layer 3. In the present example, the planar shape of the p-type second semiconductor layer 6 has been set to the rectangular frame shape for simplifying explanation. However, the planar shape of the p-type second semiconductor layer 6 is not limited to the rectangular frame shape. The p-type dopant concentration of the p-type second semiconductor layer 6 is, for example, 1×10¹⁸/cm³ to 1×10¹⁹/cm³.

In the present embodiment, the p-type second semiconductor layer 6 is, for example, a p-type dopant diffusion layer formed by implanting a p-type dopant from the front surface of the n⁻-type first semiconductor layer 5 by ion implantation, and thereafter diffusing the p-type dopant by a thermal process. However, the p-type second semiconductor layer 6 is not limited thereto. The p-type second semiconductor layer 6 may also be a growth layer embedded in a trench having a rectangular frame shape and passing through the n⁻-type first semiconductor layer 5 formed, for example, by vapor phase epitaxy.

In this example, a portion of the n⁻-type first semiconductor layer 5 that is surrounded by the p-type second semiconductor layer 6 (when viewed from above as in FIG. 2) becomes the first cathode layer 8. That is, the first cathode layer 8 is a portion of the n⁻-type first semiconductor layer 5 positioned on the inner side of the frame formed of the p-type second semiconductor layer 6.

The fourth anode layer 15 extends from the upper surface of the first cathode layer 8 but does not extend in the vertical direction completely through first cathode layer 8 to reach the first anode layer 3, but rather extends to a level that is inside the first cathode layer 8. The fourth anode layer 15 surrounds a portion of the first cathode layer 8 which ultimately becomes the fourth cathode layer 16.

As depicted in FIG. 2, the fourth anode layer 15 has a rectangular frame shape when viewed from above. The fourth anode layer 15 extends from a level at the upper surface of the n⁻-type first semiconductor layer 5 towards the first anode layer 3 while maintaining the rectangular frame shape, but the fourth anode layer 15 does not extend completely to the first anode layer 3, but rather stops at level within the first cathode layer 8. That is, a portion of the first cathode layer 8 separates the fourth anode layer 15 from the first anode layer 3. The fourth anode layer 15 is connected to the inside of the first cathode layer 8. Also, in the present example, the planar shape of the fourth anode layer 15 has been set to a rectangular frame shape for simplifying explanation. However, the planar shape of the fourth anode layer 15 is not limited to the rectangular frame shape. The p-type dopant concentration of the fourth anode layer 15 is, for example, 1×10¹⁸/cm³ to 1×10¹⁹/cm³.

The portion of the first cathode layer 8 surrounded by the fourth anode layer 15 becomes the fourth cathode layer 16. That is, the fourth cathode layer 16 is initially a portion of the first cathode layer 8 inside of the frame formed by the fourth anode layer 15.

The n⁺-type contact layer 10 is formed on the upper surface of the fourth cathode layer 16. The n⁺-type contact layer 10 has an n-type dopant concentration higher than the n-type dopant concentration of the fourth cathode layer 16. The n-type dopant concentration of the n⁺-type contact layer 10 is, for example, 1×10¹⁹/cm³ to 1×10²⁰/cm³.

The n-type third semiconductor layer 7 is adjacent to the p-type second semiconductor layer 6 and inside the n⁻-type first semiconductor layer 5 when viewed from above as in FIG. 2. The n-type third semiconductor layer 7 extends from the upper surface of the n⁻-type first semiconductor layer 5 through the n⁻-type first semiconductor layer 5, while maintaining a frame shape, and is electrically connected to the first anode layer 3 and the third cathode layer 4. That is, as shown in FIG. 2, the n-type third semiconductor layer 7 has a rectangular frame shape when viewed from above, as in FIG. 2, and extends from the upper surface of n⁻-type first semiconductor layer 5, while maintaining the rectangular frame shape, and reaches top surfaces of the first anode layer 3 and the third cathode layer 4. As depicted in FIG. 3, the entire inside lower edge of the frame formed by the n-type third semiconductor layer 7 is positioned on the third cathode layer 4.

In the present example, the planar shape of the n-type third semiconductor layer 7 has been set to the rectangular frame shape for simplifying explanation. However, the planar shape of the n-type third semiconductor layer 7 is not limited to the rectangular frame shape. The n-type dopant concentration of the n-type third semiconductor layer 7 is higher than the n-type dopant concentration of the n⁻-type first semiconductor layer 5, and is lower than the n-type dopant concentration of the third cathode layer 4. The n-type dopant concentration of the n-type third semiconductor layer 7 is, for example, 1×10¹⁸/cm3 to 1×10¹⁹/cm³.

In the present example, the n-type third semiconductor layer 7 is, for example, an n-type dopant diffusion layer formed by implanting an n-type dopant from the upper surface of the n⁻-type first semiconductor layer 5 by ion implantation, and thereafter diffusing the n-type dopant by a thermal process. However, the n-type third semiconductor layer 7 is not limited thereto. The n-type third semiconductor layer 7 may also be a growth layer formed in a trench in the n⁻-type first semiconductor layer 5. The growth layer may be formed by, for example, vapor phase epitaxy.

A portion of the n⁻-type first semiconductor layer 5 surrounded (when viewed from above as in FIG. 2) by the n-type third semiconductor layer 7 becomes the second cathode layer 9. That is, the second cathode layer 9 is initially a portion of the n⁻-type first semiconductor layer 5 inside of a frame formed of the n-type third semiconductor layer 7.

Within a plane parallel to the upper surface of the n⁻-type first semiconductor layer 5, the entire area of the second cathode layer 9 is electrically connected to the first anode layer 3 through the third cathode layer 4. That is, second cathode layer 9 is separated from first anode layer 3 by third cathode layer 4 over the entire bottom surface area of second cathode layer 9. The n-type third semiconductor layer 7 is formed on the third cathode layer 4 and the first anode layer 3 along the outer periphery (outer edge) of the third cathode layer 4. That is, n-type third semiconductor layer 7 overlaps the outer periphery of the third cathode layer 4.

In the present example, the third cathode layer 4 is formed so as not to protrude to the outside of the n-type third semiconductor layer 7. That is, in this example, the third cathode layer 4 does not extend in a direction parallel to the plane of the upper surface of n⁻-type first semiconductor layer 5 to a point beyond an outer edge of the frame formed by n-type third semiconductor layer 7. However, the present disclosure is not limited thereto. The third cathode layer 4 may extend into the n⁻-type first semiconductor layer 5 adjacent to the frame formed by the n-type third semiconductor layer 7.

The second anode layer 11 is formed on the upper surface of the second cathode layer 9. The second anode layer 11 has a p-type dopant concentration higher than the p-type dopant concentration of the first anode layer 3. The p-type dopant concentration of the second anode layer 11 is, for example, 1×10¹⁹/cm³ to 1×10²⁰/cm³.

The first electrode 13 is connected to the first anode layer 3 and the first terminal 1 is electrically connected to the first anode layer 3 through the first electrode 13.

The insulating layer 12 is formed on the n⁻-type first semiconductor layer 5, the p-type second semiconductor layer 6, the first cathode layer 8, the n-type third semiconductor layer 7, the second cathode layer 9, fourth anode layer 15, the fourth cathode layer 16, the n⁺-type contact layer 10, and the second anode layer 11.

The second electrode 14 is formed on the insulating layer 12, and is electrically connected to the n⁺-type contact layer 10 and the second anode layer 11 through openings in the insulating layer 12. The second terminal 2 is electrically connected to the n⁺-type contact layer 10 and the second anode layer 11 through the second electrode 14.

The insulating layer 12 is formed of, for example, silicon oxide; however, the insulating layer 12 is not limited to this material may also be formed of other insulating materials such as silicon nitride, silicon oxide nitride, or the like. Also, the second electrode 14 and the first electrode 13 are formed of, for example, aluminum or copper; however, the electrodes may be formed of a general wiring material or other conductive materials.

The Zener diode D3 includes the first anode layer 3 and the third cathode layer 4. The first anode layer 3 serves as the anode layer of the Zener diode D3, and the third cathode layer 4 serves as the cathode layer of the Zener diode D3. This is indicated in FIG. 3 by the superimposed Zener diode symbol on the layer structure of depicted by the figure.

The diode D2 includes the second cathode layer 9 and the second anode layer 11. The second cathode layer 9 serves as the cathode layer of the diode D2, and the second anode layer 11 serves as the anode layer of the diode D2. The cathode layer (the second cathode layer 9) of the diode D2 is stacked on the cathode layer (the third cathode layer 4) of the Zener diode D3 and are thusly electrically connected directly with each other. As a result, the contact resistance of the cathode layer (cathode layer 9) of the diode D2 and the cathode layer (third cathode layer 4) of the Zener diode D3 is reduced. The anode layer (the second anode layer 11) of the diode D2 is electrically connected to the second terminal 2 through the second electrode 14.

Also, as described above, the third cathode layer 4 may be formed to extend outwardly (in a direction parallel to the upper surface of n⁻-type first semiconductor layer 5) beyond the frame formed by the n-type third semiconductor layer 7, thereby increasing the area of the p-n junction of the third cathode layer 4 and the first anode layer 3. As a result, it is possible to reduce the on-resistance of the Zener diode D3.

The diode D1 includes the first anode layer 3 and the first cathode layer 8. The first anode layer 3 serves as the anode layer of the diode D1, and the first cathode layer 8 serves as the cathode layer of the diode D1. The anode layer (the first anode layer 3) of the diode D1 shared with the anode layer (the first anode layer 3) of the Zener diode D3, and is electrically connected to the first terminal 1.

The diode D4 includes the fourth anode layer 15 and the fourth cathode layer 16. The fourth anode layer 15 serves as the anode layer of the diode D4, and the fourth cathode layer 16 serves as the cathode layer of the diode D4. The anode layer (the fourth anode layer 15) of the diode D4 is stacked on the cathode layer (the first cathode layer 8) of the diode D1 and is thusly electrically connected directly with the cathode layer (the first cathode layer 8) of the diode D1. As a result, the contact resistance of the cathode layer of the diode D1 and the anode layer of the diode D4 is reduced. The cathode layer (the fourth cathode layer 16) of the diode D4 is electrically connected to the second electrode 14 through the n⁺-type contact layer 10, and is electrically connected to the anode layer (the second anode layer 11) of the diode D2 and the second terminal 2 through the second electrode 14.

The breakdown voltage of the semiconductor device 100 is determined by the breakdown voltage of the Zener diode D3. The breakdown voltage of the Zener diode D3 may be adjusted according to the n-type dopant concentration of the third cathode layer 4.

The operation of the semiconductor device 100 according to the first embodiment will be described. When a negative voltage is applied to the second terminal 2, the diode D1 and the diode D4 are turned on (conducting). Additionally, the Zener diode D3 is turned on (conducting), whereas the diode D2 is turned off (non-conducting). As a result, a current flows from the first terminal 1 to the second terminal 2 through the first electrode 13, the first anode layer 3, the first cathode layer 8, the fourth anode layer 15, the fourth cathode layer 16, the n⁺-type contact layer 10, and the second electrode 14. Thus, with respect to negative ESD, the semiconductor device 100 operates as described above, thereby protecting the circuit unit.

If a positive voltage is applied to the second terminal 2, and the positive voltage is equal to or lower than the breakdown voltage of the Zener diode D3, the diode D2 is turned on, whereas the diode D1, the diode D4, and the Zener diode D3 are turned off. Therefore, a current does not flow between the first terminal 1 and the second terminal 2 of the semiconductor device 100, and the applied voltage is input as an input signal to the circuit unit.

When the applied positive voltage of the second terminal 2 exceeds the breakdown voltage of the Zener diode D3, the Zener diode D3 and the diode D2 are turned on. Asa result, a current flows from the second terminal 2 to the first terminal 1 through the second electrode 14, the second anode layer 11, the second cathode layer 9, the third cathode layer 4, the first anode layer 3, and the first electrode 13. Thus, with respect to a positive ESD, the semiconductor device 100 operates as described above, thereby protecting the circuit unit.

Also, if after the Zener diode D3 has broken down the on-resistances of the Zener diode D3 and the diode D2 are high, it is possible that some significant portion of the ESD current does not discharge through the protective semiconductor device 100, but rather flows into the circuit unit, potentially causing damage to the circuit unit. That is, the protective function of the semiconductor device for protection from ESD is not fully realized. Therefore, it is preferable for the on-resistance of the semiconductor device 100 to be low.

In the semiconductor device 100 according to the present embodiment, since the diode D2 and the Zener diode D3 are connected in series, there is a possibility that the resistance of the contact portion of the diode D2 and the Zener diode D3 will increase. However, as the second cathode layer 9, which is the cathode layer of the diode D2, is stacked directly on the third cathode layer 4, which is the cathode layer of the Zener diode D3 it is possible to keep the contact resistance of the cathode layer of the diode D2 and the cathode layer of the Zener diode D3 low, and consequently in the semiconductor device 100, it becomes possible to reduce the on-resistance relative to positive ESD.

Also, as to the semiconductor device 100, the Zener diode D3 and the diode D2 are connected in series, and the diode D1 and the diode D4 are connected in series. The sum of the electrostatic capacitances of the diode D2 and the Zener diode D3 connected in series may be expressed as the following Equation 1. Here, since the electrostatic capacitance C3 has a very large value, the sum of the electrostatic capacitances of the diode D2 and the Zener diode D3 is substantially equal to the electrostatic capacitance C2 (i.e., the contribution of 1/C3 to the capacitance sum is relatively insignificant).

$$\begin{matrix}[ Equation 1 ] & \\ \frac{1}{\frac{1}{C 2} + \frac{1}{C 3}} & ( 1 )\end{matrix}$$

Meanwhile, the sum of the electrostatic capacities of the diode D1 and the diode D4 connected in series may be expressed as the following Equation 2. For example, if the values of the electrostatic capacitance C1 and the electrostatic capacitance C4 are the same, the sum of the electrostatic capacitances of the diode D1 and the diode D4 becomes half of the electrostatic capacitance C1 (or C4).

$$\begin{matrix}[ Equation 2 ] & \\ \frac{1}{\frac{1}{C 1} + \frac{1}{C 4}} = \frac{C 1 \times C 4}{C 1 + C 4} & ( 2 )\end{matrix}$$

Since the series-connected diode D2 and the Zener diode D3 are connected in parallel with the series-connected diode D1 and the diode D4, the total (overall) electrostatic capacitance of the semiconductor device 100 may be obtained by the sum of the Equation 1 and the Equation 2. Therefore, since the diode D2 is connected in series to the Zener diode D3, the electrostatic capacitance of the semiconductor device 100 is not significantly influenced by the Zener diode D3 (though the influence may still be greater than zero). The values of the electrostatic capacitances of the diode D1, the diode D2, and the diode D4 are considerably lower than the electrostatic capacitance of the Zener diode D3. Therefore, it becomes possible to reduce the total apparent electrostatic capacitance of the semiconductor device 100.

Furthermore, since the cathode layer (the second cathode layer 9) of the diode D2 is stacked directly on the cathode layer (the third cathode layer 4) of the Zener diode D3, the on-resistance is reduced.

Also, in the semiconductor device 100, the diode D2 is formed to be stacked directly on the Zener diode D3. For this reason, as compared to a case where the diode D2 and the Zener diode D3 are formed in parallel in a horizontal direction (e.g., in the same plane) on the first anode layer 3, it is possible to reduce the chip area of the semiconductor device 100.

Furthermore, in the semiconductor device 100, the third cathode layer 4 has a structure in which the third cathode layer 4 does not protrude outwardly beyond the frame of the n-type third semiconductor layer 7. However, since the third cathode layer 4 can be formed to extend into the n⁻-type first semiconductor layer 5 positioned on the outside of the frame of the n-type third semiconductor layer 7, it is possible to increase the area of the p-n junction of the Zener diode D3. As a result, since the on-resistance of the Zener diode D3 is reduced, the on-resistance of the semiconductor device 100 is further reduced. In contrast to this, the electrostatic capacitance of the Zener diode D3 increases, but in the semiconductor device 100, the electrostatic capacitance of the semiconductor device 100 is not substantially influenced by the increase in the electrostatic capacitance of the Zener diode D3. Thus, even in this case, the effective electrostatic capacitance of the semiconductor device 100 may be kept low.

Also, in the first embodiment, only the diode D4 has been connected in series to the diode D1, and only the diode D2 has been connected in series to the Zener diode D3. However, the number of diodes to be connected in series is not especially limited.

### Second Embodiment

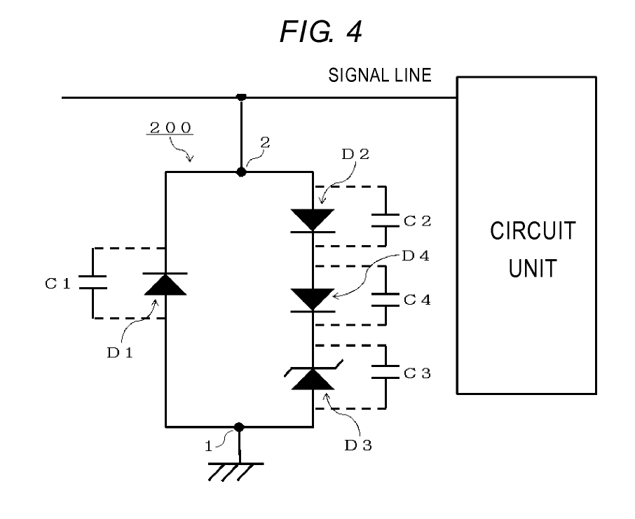

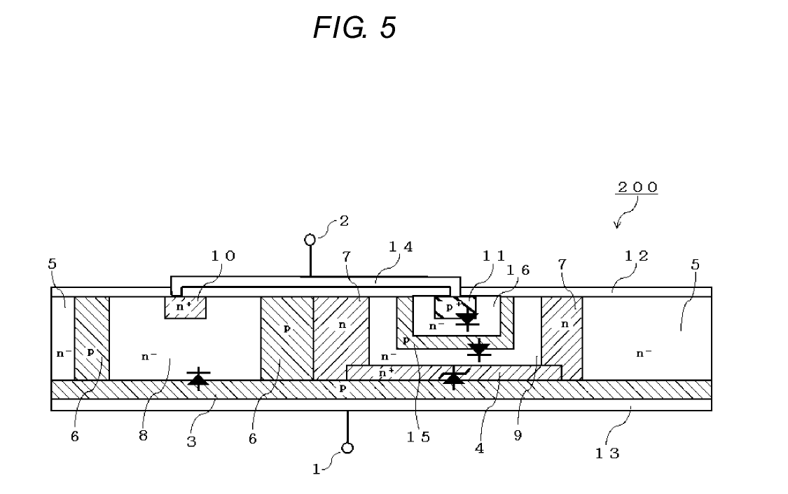

A semiconductor device 200 according to a second embodiment will be described with reference to FIGS. 4 and 5. FIG. 4 shows an equivalent circuit of the semiconductor device 200 according to the second embodiment, and FIG. 5 is a cross-sectional view of the semiconductor device 200. Components substantially similar to components described in the first embodiment are denoted by the same reference numbers or symbols, and may not be described again so that differences from the first embodiment can be described.

As depicted in FIG. 5, in semiconductor device 200, the diode D4 is connected in series between the diode D2 and the Zener diode D3. The anode of the diode D4 is connected to the cathode of the diode D2, and the cathode of the diode D4 is connected to the cathode of the Zener diode D3.

An example structure of semiconductor device 200 will be described with reference to FIG. 5. In the case of the semiconductor device 200, in the first cathode layer 8 surrounded by the p-type second semiconductor layer 6, only the n⁺-type contact layer 10 is formed. Meanwhile, in the second cathode layer 9 surrounded by the n-type third semiconductor layer 7, the fourth anode layer 15 is formed to extend from the upper surface of the second cathode layer 9 to a level inside the second cathode layer 9, and shaped so as to surround a portion of the second cathode layer 9 that ultimately becomes fourth cathode layer 16. A bottom surface of the fourth anode layer 15 is connected to the second cathode layer 9. That is, the fourth anode layer 15 extends into the second cathode layer 9 and the bottom of the fourth anode layer 15 is inside the second cathode layer 9 rather than extending completely through the second cathode layer 9 to reach the third cathode layer 4. The portion of the second cathode layer 9 surrounded by the fourth anode layer 15 becomes the fourth cathode layer 16. The second anode layer 11 is formed in the upper surface of the fourth cathode layer 16.

The semiconductor device 200 is different from the semiconductor device 100 in the above-described points, and is the substantially the same as the semiconductor device 100 in the other structure.

Even with respect to the semiconductor device 200 according to the second embodiment, the diode D1 having electrostatic capacitance lower than that of the Zener diode D3 is connected in parallel with the series-connected Zener diode D3, and the diode D2 and the diode D4. Diode D2 and diode D4 each have electrostatic capacitance lower than that of the Zener diode D3, and thus the apparent electrostatic capacitance of the semiconductor device 200 is not substantially influenced by the Zener diode D3. As a result, it becomes possible to reduce the total apparent electrostatic capacitance of the semiconductor device 200. The other effects of the semiconductor device 200 are also the same as those of the semiconductor device 100.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electrostatic discharge protection device, comprising:
a first terminal at a first potential;
a second terminal to be connected to a signal line;
a first diode connected between the first and second terminals and having an anode connected to the first terminal;
a second diode and a third diode connected in series between the first and second terminals and in parallel with the first diode between the first and second terminals, the second diode having an anode connected to the second terminal and the third diode having an anode connected to the first terminal, wherein
the third diode is a Zener diode having a capacitance that is greater than each of a capacitance of the first diode and a capacitance of the second diode.

2. The electrostatic discharge protection device according to claim 1, further comprising a fourth diode connected between the first and second terminals in series with the first diode, an anode of the fourth diode connected to a cathode of the first diode and a cathode of the fourth diode connected to the second terminal, wherein the capacitance of the third diode is greater than a capacitance of the fourth diode.

3. The electrostatic discharge protection device according to claim 1, further comprising a fourth diode connected between the first and second terminals in series with the second and third diodes, an anode of the fourth diode connected to a cathode of the second diode and a cathode of the fourth diode connected to the cathode of the third diode, wherein the capacitance of the third diode is greater than a capacitance of the fourth diode.

4. The electrostatic discharge protection device according to claim 1, wherein the signal line is attached to the second terminal and a circuit unit.

5. The electrostatic discharge protection device according to claim 1, wherein the first potential is a ground potential.

6. The electrostatic discharge protection device according to claim 1, wherein the at least the third diode and the second diode comprise semiconductor regions that are disposed on each other in a stacked arrangement between a first electrode layer electrically connected to the first terminal and a second electrode layer electrically connected to the second terminal.

7. A semiconductor device, comprising:
a first semiconductor layer with a second conductivity-type and in electrical contact with a first electrode;
a first semiconductor region with a first conductivity-type disposed on a first surface of the first semiconductor layer and having a first conductivity-type dopant concentration at a first concentration level;
a second semiconductor region with the second conductivity-type disposed on the first surface and surrounding the first semiconductor region in a plane parallel to the first surface;
a third semiconductor region with the first conductivity-type disposed on the first surface and spaced apart from the first semiconductor region by at least the a portion of the second semiconductor region and having a first conductivity-type dopant concentration at a second concentration level that is greater than the first concentration level;
a fourth semiconductor region with the second conductivity-type disposed on the first semiconductor region and surrounded by the first semiconductor region in a plane parallel to the first surface;
a fifth semiconductor region with the first conductivity type disposed on the fourth semiconductor region, surrounded by the fourth semiconductor region in a plane parallel to the first surface, and having a first conductivity-type dopant concentration at a concentration level less than the second concentration level;
a sixth semiconductor region with the first conductivity-type disposed adjacent to the second semiconductor region with at least a portion on a surface of the third semiconductor region such that the third semiconductor region is between the portion and the first surface and having a first conductivity-type dopant concentration at a concentration level that is greater than the first concentration level and less than the second concentration level;
a seventh semiconductor region with the first conductivity-type disposed on the surface of the third semiconductor region, surrounded in a plane parallel to the first surface by the sixth semiconductor region, and having a first conductivity-type dopant concentration at a concentration level that is less than the second concentration level; and
an eighth semiconductor region with the second conductivity type disposed on a surface of the fifth semiconductor region, surrounded in a plane parallel to the first surface by the fifth semiconductor region, and having a second conductivity-type dopant concentration that is greater than a second conductivity-type dopant concentration of the first semiconductor layer, wherein
the fifth semiconductor region and the eight semiconductor region are in electrical contact with a second electrode.

8. The semiconductor device according to claim 7, further comprising:
a ninth semiconductor region with the first conductivity-type disposed on a surface of the fifth semiconductor region, surrounded in a plane parallel to the first surface by the fifth semiconductor region, and having a first conductivity-type dopant concentration at a concentration level that is greater than the second level, wherein the second electrode is in electrical contact with fifth semiconductor region via the ninth semiconductor region.

9. The semiconductor device according to claim 7, wherein the second semiconductor region has a rectangular shape when viewed from a direction orthogonal to the first surface.

10. The semiconductor device according to claim 7, wherein seventh semiconductor region extends beyond an outer edge of the sixth semiconductor region when viewed from a direction orthogonal to the first surface.

11. The semiconductor device according to claim 7, further comprising:
an insulating film disposed between the second electrode and the sixth semiconductor region and between the second electrode and the second semiconductor region.

12. The semiconductor device according to claim 7, wherein each semiconductor region comprises silicon.

13. The semiconductor device according to claim 7, further comprising:
a ninth semiconductor region with the first conductivity type disposed on the first surface, surrounding the first through eighth semiconductor regions in a plane parallel to the first surface, and having a first conductivity-type dopant concentration at a concentration level that is less than the second concentration level.

14. The semiconductor device according to claim 7, wherein the concentration level of the first conductivity-type dopant concentration of the fifth semiconductor layer equals the first concentration level.

15. A semiconductor device, comprising:
a first semiconductor layer with a second conductivity-type and in electrical contact with a first electrode;
a first semiconductor region with a first conductivity-type disposed on a first surface of the first semiconductor layer and having a first conductivity-type dopant concentration at a first concentration level;
a second semiconductor region with the second conductivity-type disposed on the first surface and surrounding the first semiconductor region in a plane parallel to the first surface;
a third semiconductor region with the first conductivity-type disposed on the first surface and spaced apart from the first semiconductor region by at least the a portion of the second semiconductor region and having a first conductivity-type dopant concentration at a second concentration level that is greater than the first concentration level;
a fourth semiconductor region with the first conductivity-type disposed adjacent to the second semiconductor region with at least a portion on a surface of the third semiconductor region such that the third semiconductor region is between the portion and the first surface and having a first conductivity-type dopant concentration at a concentration level that is greater than the first concentration level and less than the second concentration level;
a fifth semiconductor region with the first conductivity-type disposed on the surface of the third semiconductor region, surrounded in a plane parallel to the first surface by the fourth semiconductor region, and having a first conductivity-type dopant concentration at a concentration level that is less than the second concentration level;
a sixth semiconductor region with the second conductivity-type disposed on the fifth semiconductor region and surrounded by the fifth semiconductor region in a plane parallel to the first surface;
a seventh semiconductor region with the first conductivity type disposed on the sixth semiconductor region, surrounded by the sixth semiconductor region in a plane parallel to the first surface, and having a first conductivity-type dopant concentration at a concentration level less than the second concentration level; and
an eighth semiconductor region with the second conductivity type disposed on a surface of the seventh semiconductor region, surrounded in a plane parallel to the first surface by the seventh semiconductor region, and having a second conductivity-type dopant concentration that is greater than a second conductivity-type dopant concentration of the first semiconductor layer, wherein
the first semiconductor region and the eight semiconductor region are in electrical contact with a second electrode.

16. The semiconductor device according to claim 15, further comprising:
a ninth semiconductor region with the first conductivity-type disposed on a surface of the first semiconductor region, surrounded in a plane parallel to the first surface by the first semiconductor region, and having a first conductivity-type dopant concentration at a concentration level that is greater than the second level, wherein the second electrode is in electrical contact with first semiconductor region via the ninth semiconductor region.

17. The semiconductor device according to claim 15, wherein the second semiconductor region has a rectangular shape when viewed from a direction orthogonal to the first surface.

18. The semiconductor device according to claim 15, wherein third semiconductor region extends beyond an outer edge of the fourth semiconductor region when viewed from a direction orthogonal to the first surface.

19. The semiconductor device according to claim 15, further comprising:
an insulating film disposed between the second electrode and the fourth semiconductor region and between the second electrode and the second semiconductor region.

20. The semiconductor device according to claim 15, wherein the concentration level of the first conductivity-type dopant concentration of the seventh semiconductor layer equals the first concentration level.
